(19) United States
(12) Patent Application Publication
(10) Pub. No.: US 2014/0239191 A1
(43) Pub. Date: Aug. 28, 2014

(54) Method for Uninterrupted Production of a Polyatomic Boron Molecular Ion Beam with Self-Cleaning

(71) Applicants: Ady Itzchak Hershcovitch, Mount Sinai, NY (US); Oleg Alexeyenko, Moscow (RU); Timur Kulevoy, Moscow (RU); Rostislav Kuibeda, Moscow (RU); Efim Oks, Tomsk (RU); Vasiliy Gushenets, Tomsk (RU); Pavel Storozhenko, Moscow (RU); Ella Gurkova, Moscow (RU); Sergey Dugin, Moscow (RU); Gennady Kropachev, Moscow (RU); Dimitri Seleznev, Podolsk Moscow Region (RU)

(72) Inventors: Ady Itzchak Hershcovitch, Mount Sinai, NY (US); Oleg Alexeyenko, Moscow (RU); Timur Kulevoy, Moscow (RU); Rostislav Kuibeda, Moscow (RU); Efim Oks, Tomsk (RU); Vasiliy Gushenets, Tomsk (RU); Pavel Storozhenko, Moscow (RU); Ella Gurkova, Moscow (RU); Sergey Dugin, Moscow (RU); Gennady Kropachev, Moscow (RU); Dimitri Seleznev, Podolsk Moscow Region (RU)

(21) Appl. No.: 14/129,812

(22) PCT Filed: Jul. 20, 2012
(86) PCT No.: PCT/US2012/047626

§ 371 Date: Apr. 21, 2014

(30) Foreign Application Priority Data
Aug. 3, 2011 (RU) 2011132717

(51) Int. Cl. H01J 37/08; C07F 5/05

(52) U.S. Cl. CPC H01J 37/08; C07F 5/05; H01J 2237/0815
USPC 250/424; 568/5; 562/594

(57) ABSTRACT

The uninterrupted production of an ion beam with self-cleaning of a discharge chamber and extractor system, including extraction aperture(s), of an ion implantation device. The method increases the time of continuous operation of the ion implantation device, and therefore, increases total implantation time without reducing intensity. As a result, the time integrated output of the ion implantation device is increased. The method includes feeding a working molecule comprising at least two boron atoms and a strong oxidizer into an ion implantation device and removing gaseous compounds from the ion implantation device, wherein said working molecule provides upon fragmentation a polyatomic boron-containing ion, and the strong oxidizer which reacts with solid products of decomposition of the working molecule to form said gaseous compounds. A working molecule including at least two boron atoms and at least one strong oxidizer is also disclosed. Examples of the working molecule include C₄H₁₂B₁₀O₄, such as 1,7-m-carborane dicarboxylic acid or o-carborane-1,2-dicarboxylic acid.

### STATEMENT OF GOVERNMENT LICENSE RIGHTS

This invention was made with Government support under contract number DE-AC02-98CH10886, awarded by the U.S. Department of Energy. The Government has certain rights in the invention.

### CROSS-REFERENCE TO RELATED APPLICATIONS

This application claims the benefit of priority from Russian Application Bearing Registration No. 2011132717 and a filing date of Aug. 3, 2011, the disclosure of which is incorporated herein by reference.

### FIELD OF THE INVENTION

The field of the invention relates to self-cleaning of an ion source, including a discharge chamber and an extraction system, of a gas-filled discharge instrument while at the same time generating molecular ions for implantation into, e.g., silicone wafers during semiconductor manufacture.

### BACKGROUND

Since the invention of the semiconductor transistor there has been constant work toward miniaturization of semiconductor devices. A reduction of the dimensions of semiconductor devices creates a need to use low-energy ion beams at a level of several hundred eV to one keV. However, according to the Child-Langmuir law, a reduction in energy of the ion beam reduces the intensity of the beam as dictated by the intrinsic space charge of the beam. Thus, the reduction in the energy of the ion beam produces a reduction in the output (i.e., the amount of ions implanted) of an ion implantation device.

One of the ways to overcome the limitations of low-energy ion beams is to use beams of polyatomic molecular ions. Using polyatomic molecular ion results in far more atoms of the implant material per ion. In particular, polyatomic boron-containing molecular beams are used for implantation of boron ions. For example, beams of carborane, decacarborane, and octadecarborane ions are used. The use of such polyatomic ions makes it possible to obtain the energy required for implantation by using an accelerating voltage k times greater than for atomic ions (k=Mm/Ma, where Mm is the molecular weight of the molecular ion, Ma is the atomic weight of a boron ion or other required substance). Thus, per the Child-Langmuir law, the intensity limit of the ion beam is increased. Moreover, one electric charge of the molecular ion can implant N times greater number of boron atoms than an atomic ion, where N is the number of boron atoms in the molecular ion.

However, during generation of ions of polyatomic substances, decomposition occurs due to molecular fracturing. The products of this decomposition are deposited on the discharge chamber and extraction system, contaminating them, including partially covering the extraction apertures, e.g., in the plasma electrode and accelerating electrodes. Covering the extraction apertures leads to an uncontrollable and undesirable change in the ion beam profile. Essentially, covering the extraction apertures produces shadows of the implantation in the wafer. Accordingly, in order to maintain the quality of the ion beam during implantation it is important to keep the extraction apertures free of deposits. Thus, the maintenance of ion beam quality makes the cleaning of the discharge chamber and extraction system necessary.

The method closest to the self-cleaning method described herein, in terms of combined features, is a chemical method of cleaning (International Application No. WO 2011/041223 (A1), IPC C23C14156; HO1J37108; H01 J37116; HO1J3713 1; published Apr. 7, 2011), which relies on substances, such as fluorine or oxygen, or their mixture, being introduced into the discharge chamber of the ion source. The substances then chemically react with the products of decomposition of the polyatomic molecular ions deposited on the extraction system and walls of the discharge chamber to form gaseous compounds. The gaseous compounds are then eliminated during vacuum pumping of the discharge chamber. This cleaning process can be conducted with the complete shutdown of the source or during generation of the ion beam.

The cleaning of the extraction system and the discharge chamber with complete shutdown of the ion source results in an increase in the downtime of the ion implantation device, and thus, a reduction in the time integrated output of the ion implantation device.

Moreover, the cleaning of the discharge chamber by introduction of strong oxidizer (for example, fluorine) simultaneously with the process of generation of the ion beam produces an extracted beam consisting a large number of ions of strong oxidizer and its products at the expense of the desired ions; even though the ions are easily separated by an ion beam separation system, this method nevertheless reduces the ion implantation rate.

### SUMMARY

A method for uninterrupted production of an ion beam with self-cleaning of a discharge chamber and extractor system, including extractor aperture(s), of an ion implantation device is disclosed. The method increases the time of continuous operation of the ion implantation device, and therefore, increases total implantation time without reducing intensity. As a result, the time integrated output of the ion implantation device is increased. The method includes feeding a working molecule comprising at least two boron atoms and a strong oxidizer into an ion implantation device and removing gaseous compounds from the ion implantation device, wherein said working molecule provides upon fragmentation a polyatomic boron-containing ion, and the strong oxidizer which reacts with solid products of decomposition of the working molecule to form said gaseous compounds.

Also disclosed is a working molecule comprising at least two boron atoms and at least one strong oxidizer. A particular working molecule has the formula C₄H₁₂B₁₀O₄, such as 1,7-m-carborane dicarboxylic acid (C₄H₁₂B₁₀O₄) or o-Carborane-1,2-dicarboxylic acid (C₄H₁₂B₁₀O₄).

The present method increases the time of continuous operation of the ion implantation device without reducing total implantation time or reducing intensity. As a result, the time integrated output of the ion implantation device is increased.

For a better understanding of the present method and working molecule, together with other and further objects, reference is made to the following description, taken in conjunction with the accompanying drawings, and its scope will be pointed out in the appended claims.

### BRIEF DESCRIPTION OF THE DRAWINGS

FIG. 1 is a diagram of a typical ion source of an implantation device.

FIG. 2 is a photograph of a copper discharge chamber of an implantation device after operation using carborane.

FIG. 3 is a photograph of a copper discharge chamber of an implantation device after operation using 1,7-m-carborane dicarboxylic acid.

FIG. 4 is a photograph of a copper discharge chamber of an implantation device after operation using 1,2-bis(hydroxymethyl)-o-carborane.

FIG. 5 is a photograph of a molybdenum discharge chamber of an implantation device after operation using 1,7-m-carborane dicarboxylic acid.

FIG. 6 is a photograph of a extraction aperture of a molybdenum discharge chamber of an implantation device after operation using 1,7-m-carborane dicarboxylic acid.

### DETAILED DESCRIPTION

The present method includes introduction of a working molecule into an ion implantation device to replace the typical feed gas, such as carborane, to produce polyatomic boron-containing ions. The working molecules contain at least two boron atoms and at least one strong oxidizer.

As used herein, the term “working molecule” means a molecule or compound that may be used in the operation of an ion implantation device to produce polyatomic boron-containing ions that are then implanted into, for example, a silicon wafer for semiconductor production. Thus, working molecules contain at least two boron atoms. Examples of polyatomic boron-containing ions include carborane ions, decaborane ions, and octadecaborane ions.

Moreover, the working molecule also contains a strong oxidizer. As used herein, the term “strong oxidizer” means a molecule or atom that readily reacts with other solid substances, e.g., solid products of decomposition of the working molecule, to form gaseous compounds. Examples of strong oxidizers include oxygen, fluorine, chlorine, and organic acids. Preferred strong oxidizers include oxygen, fluorine, and carboxylic acid.

Examples of working molecules include 1,7-m-carborane dicarboxylic acid (C₄H₁₂B₁₀O₄), o-Carborane-1,2-dicarboxylic acid (C₄H₁₂B₁₀O₄), 1,2-bis(hydroxymethyl)-o-carborane, C₂B₁₀H₉F₃, and decacarborane with one or more of the hydrogen atoms substituted by fluorine, and octadecacarborane with one or more of the hydrogen atoms substituted by fluorine. 1,7-m-carborane dicarboxylic acid has the following structure:

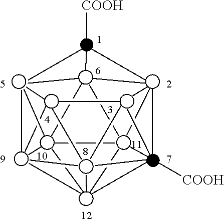

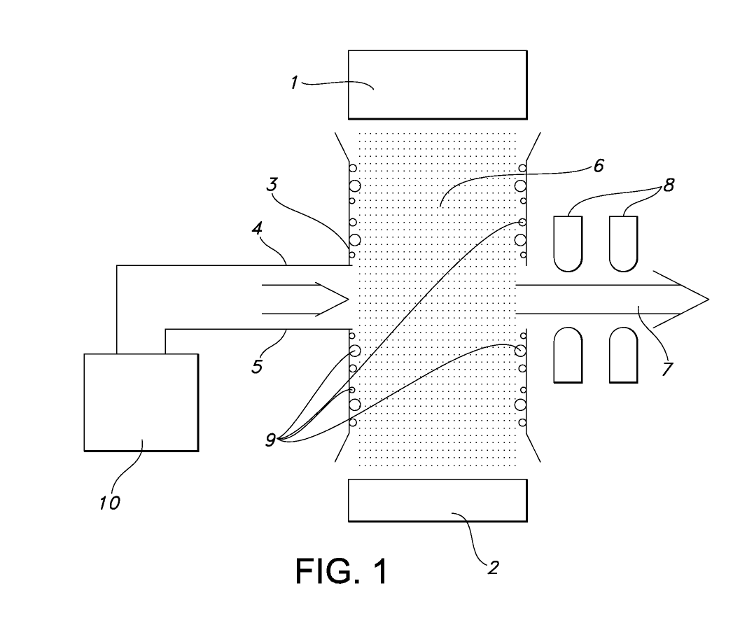

Typical operation of ion implantation devices is well known in the art. Turning to FIG. 1, a feed gas 5 is fed in the gaseous state from an oven 10 though the vapor line 4 into the discharge chamber 6, which consists of cathode 1, anticathode 2 and anode 3. Ionization of the feed gas 5 occurs in the discharge chamber 6 in an electromagnetic field created by the difference in potentials between the cathode/anticathode 1/2 and anode 3 and an external magnet with formation of plasma. During this process, in addition to ionization of the feed gas, with subsequent formation of ion beam 7 by the extraction system 8, partial dissociation of the molecules of the feed gas 5 occurs with deposition of solid products of decomposition of the feed gas 9 in the vapor line 4, the discharge chamber 6, and the extraction system 8, including on the extraction aperture(s).

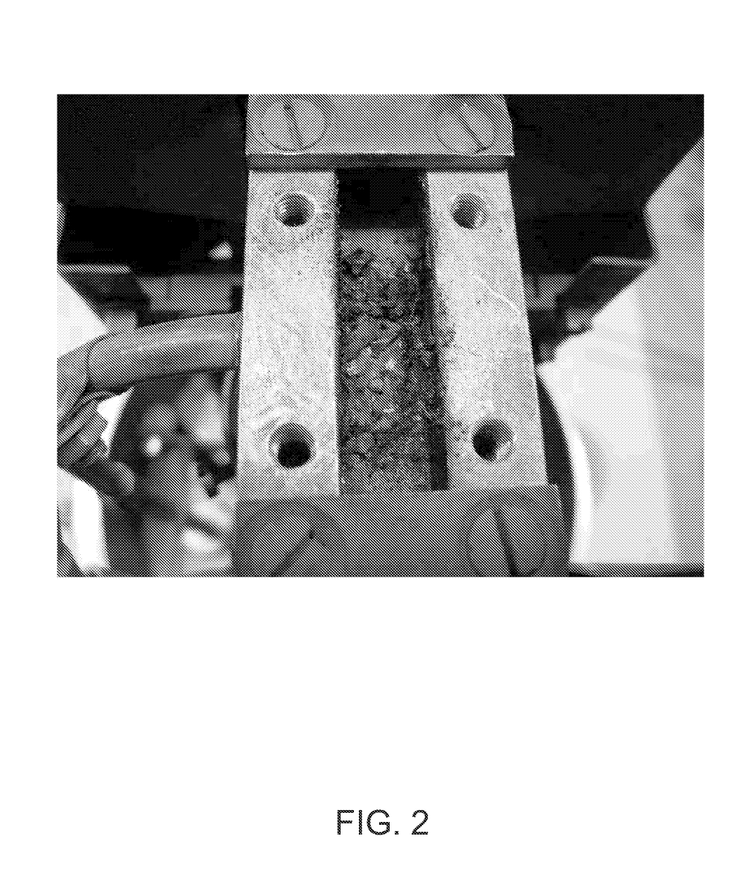

Thus, the operation of the ion implantation device typically results in a build-up of solid products of decomposition in the vapor line 4, discharge chamber 6, and the extraction system 8, including partially covering the extraction aperture(s), e.g., electrodes, slits, grids, and the like. FIG. 2 is a photograph of the discharge chamber of a copper implantation device after typical operation using carborane as the feed gas. As discussed above, this build-up of solid decomposition products can cover the extraction aperture and degrade the quality of the ion beam, producing shadows on, for example, the silicone wafer. In such instances it is desirable to clean the discharge chamber and extraction system to maintain the quality of the ion beam.

An embodiment of the present method is described below. Turning again to FIG. 1, the carborane is replaced with a working molecule as described herein. The working molecule (typically a solid) is heated in the oven 10 and fed in the gaseous state 5 into the discharge chamber 6 through the vapor line 4. Fragmentation of the working molecule 5 occurs in the vapor line 4 as well as in the discharge chamber 6 in an electromagnetic field created by the difference in potentials between the cathode/anticathode 1/2 and anode 3 and an external magnet with formation of plasma. During these processes, in addition to ionization of the working molecule with subsequent formation of the ion beam 7 by the extraction system of the ion beam 8, partial dissociation of the working molecules 5 occurs resulting in the creation of solid products of decomposition 9 of the working molecule in the vapor line 4, discharge chamber 6, and the extraction system 8, including the extraction aperture(s).

However, as a result of the fragmentation of the working molecule 5 liberation of atoms and molecules of the strong oxidizers also occurs. The strong oxidizers react with solid products of decomposition to form gaseous compounds. Thus, the buildup of solid products of decomposition in the vapor line, discharge chamber, and extraction system is avoided. The gaseous compounds are eliminated from the discharge chamber, by for example, continuous vacuum pumping. Thus, continuous self-cleaning of the discharge chamber and extraction system is achieved.

Accordingly, the general scheme of the present method may include: a) optimizing the operating conditions of the ion source; b) feeding a working molecule comprising two or more boron atoms and at least one strong oxidizer into the discharge chamber; c) operating the ion source; d) fragmenting the working molecule to produce: 1) polyatomic boron-containing ions containing all boron ions of the working molecule, 2) solid products of decomposition of the working molecule, and 3) a strong oxidizer that reacts with the solid products of decomposition of the working molecule to form gaseous compounds; and e) removing the gaseous compounds from the discharge chamber. Solid products of decomposition of the working molecule are typically by-products of decomposition of the polyatomic boron-containing portion of the working molecule. For example, in the case of 1,7-m-carborane dicarboxylic acid, the solid product of decomposition is carbon, i.e. graphite, from the carborane portion of the working molecule.

Typically, the operating conditions or parameters of the ion source are optimized As used herein, “optimized” means the operating conditions or parameters are chosen to produce the greatest output of ions containing all of the boron atoms of the working molecule while also minimizing production of unwanted ions from the fragmentation of the working molecule. The conditions or parameters required to achieve optimization are dependent on both the particular ion source employed and the working molecule used. Preferably, the vapor line may be heated prior to the introduction of a vapor of the working molecule to enhance this optimization.

Generally, the vapor line is pre-heated to from about 50° C. to about 150° C. The oven, which contains the working molecule, is then heated to from about 20° C. to about 220° C. The vapor of the working molecule travels from the oven through the channel of the heated vapor line (typically having an internal diameter of about 3 to about 10 millimeters) to the discharge chamber. When the vapor of the working molecule enters the discharge chamber, the discharge ignites. The base pressure before introduction of working molecule vapor and discharge ignition (outside the ion source) is about 1×10⁻⁵ mbar (7.5×10⁻⁶ Torr) or lower. Once the discharge is ignited the pressure increases to about 5 to 6×10⁻⁵ mbar (about 3.75-4.5×10⁻⁵ Torr) or lower.

For example, using a small, water-cooled, Bernas ion source and 1,7-m-carborane dicarboxylic acid as the working molecule, the conditions are optimized to produce the maximum output of carborane ions for implantation. An ion source of this type is described in D. Seleznev, G. Kropachev, A. Kozlov, R. Kuibeda, V. Koshelev, T. Kulevoy, A. Hershcovitch, B. Johnson, J. Poole, O. Alekseenko, E. Gurkina, E. Oks, V. Gushenets, S. Polozov, E. Masunov, “Carborane Beam from ITEP Bernas IS for Semiconductor Implanters” Rev. Sci. Instrum. 81, 02B901 (2010). The operation may be optimized as follows: the vapor line is pre-heated to about 100° C. The oven, which contains the working molecule, is then heated to from about 20° C. to about 220° C. The vapor of the working molecule travels from the oven through the heated vapor line to the discharge chamber. The vapor line has an internal diameter of about 6 mm, except at the entrance to the discharge chamber where the internal diameter narrows to about 5 millimeters. When the vapor of the working molecule enters the discharge chamber, the discharge ignites. Typical discharge parameters for this ion source are a discharge current of about 100 mA and a discharge voltage of about 100 to 150 volts. The base pressure before introduction of working molecule vapor and discharge ignition (outside the ion source) is about 1×10⁻⁵ mbar (7.5×10⁻⁶ Torr) or lower. Once discharge is ignited the pressure increases to about 5 to 6×10⁻⁵ mbar (about 3.75-4.5×10⁻⁵ Torr) or lower.

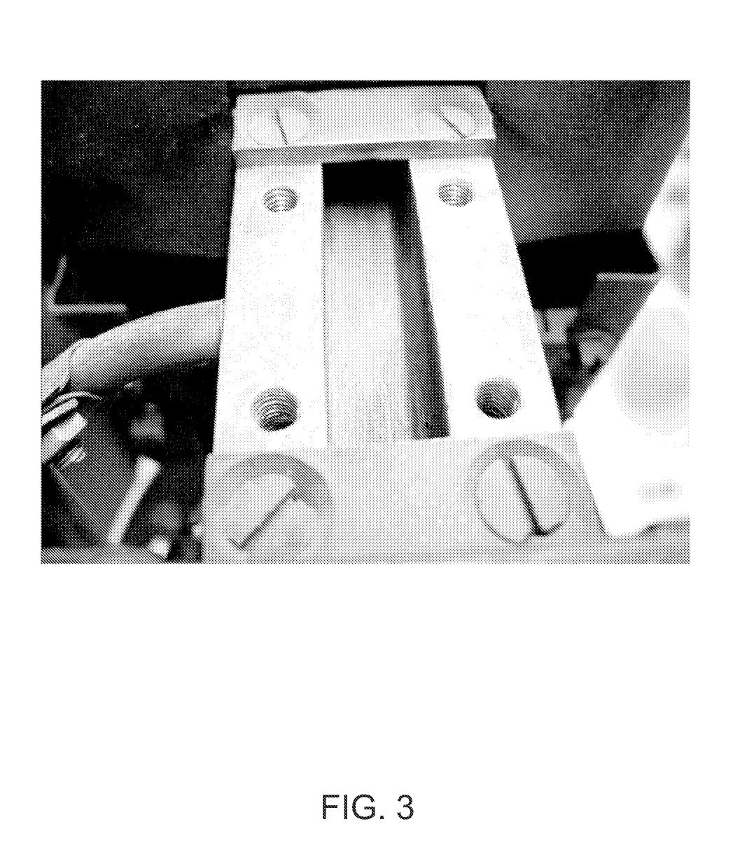

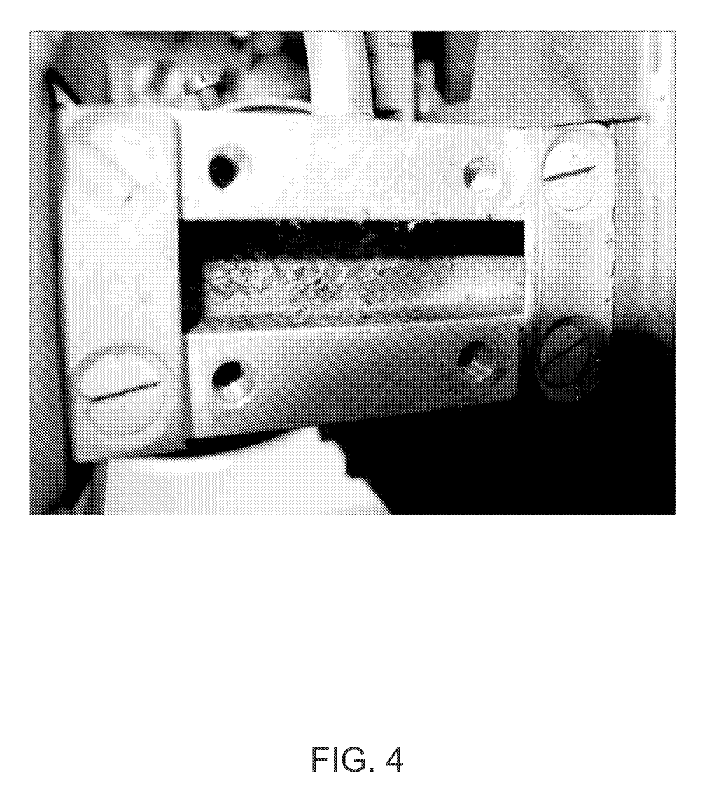

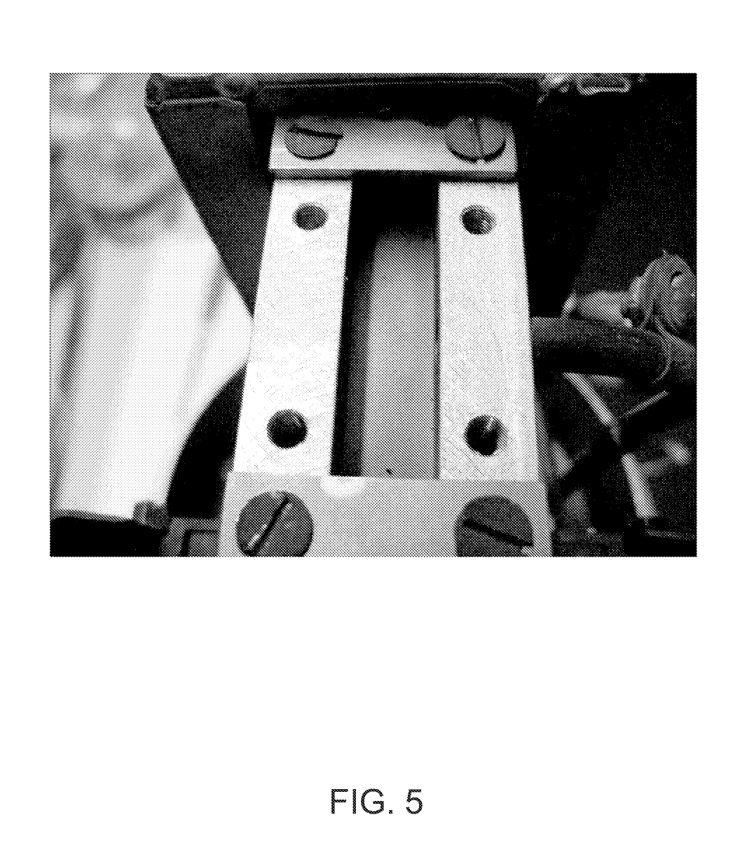

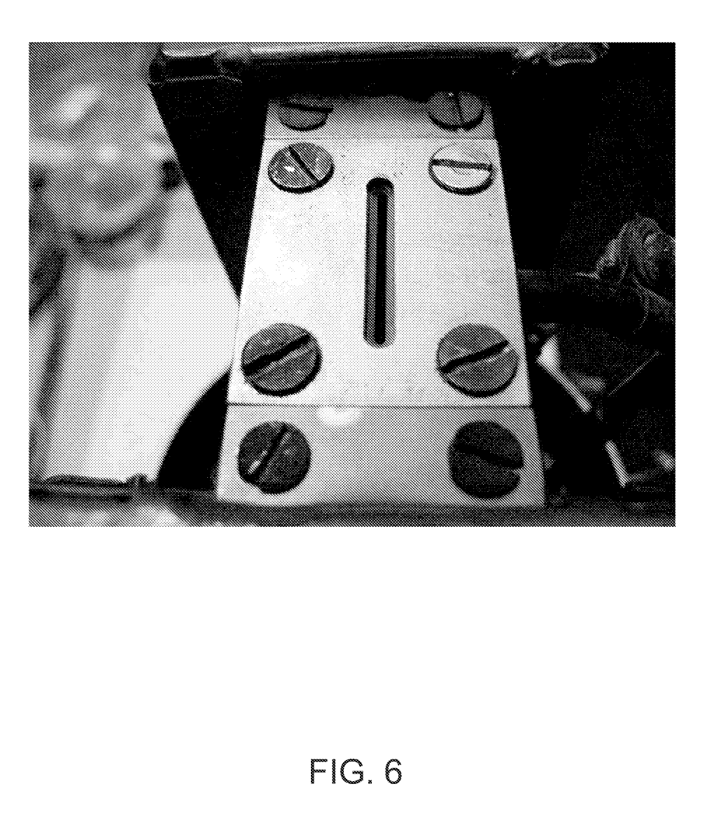

FIG. 3 is a photograph of the copper discharge chamber of an implantation device after operation according to the present method using 1,7-m-carboranedicarboxylic acid (C₄H₁₂B₁₀O₄) as the working molecule. FIG. 4 is a photograph of a copper discharge chamber of an implantation device after operation using 1,2-Bis(hydroxymethyl)-o-carborane. FIG. 5 is a photograph of a molybdenum discharge chamber of an implantation device after operation using 1,7-m-carborane dicarboxylic acid. FIG. 6 is a photograph of a molybdenum discharge chamber extraction aperture of an implantation device after operation using 1,7-m-carborane dicarboxylic acid. In the present method, the decomposition products are not deposited on the surface of the discharge chamber or extraction system, and degradation of the ion beam is avoided, while maintaining continuous operation of the ion implantation device, and therefore, uninterrupted production of the ion beam.

Thus, while there have been described what are presently believed to be the preferred embodiments, other and further embodiments will be appreciated by those skilled in the art, and it is intended to include such other embodiments as coming within the true scope of the invention as pointed out in the claims.

1. A method for uninterrupted production of an ion beam with self-cleaning of an ion implantation device comprising 1) feeding a working molecule comprising at least two boron atoms and a strong oxidizer into an ion implantation device and 2) removing gaseous compounds from the ion implantation device, wherein said working molecule provides upon fragmentation i) a polyatomic boron-containing ion, and (ii) the strong oxidizer which reacts with solid products of decomposition of the working molecule to form said gaseous compounds.

2. A method according to claim 1, wherein the strong oxidizer is selected from the group consisting of oxygen, fluorine, chlorine, and organic acid.

3. A method according to claim 2, wherein the strong oxidizer is oxygen or carboxylic acid.

4. A method according to claim 1, wherein the working molecule provides a carborane ion upon fragmentation.

5. A method according to claim 1, wherein the working molecule has the formula C₄H₁₂B₁₀O₄ or C₂B₁₀H₉F₃.

6. A method according to claim 5, wherein the working molecule is 1,7-m-carboranedicarboxylic acid or 1,2-bis(hydroxymethyl)-o-carborane.

7. A method according to claim 1, wherein the working molecule is decacarborane with one or more of the hydrogen atoms substituted by a strong oxidizer or octadecacarborane with one or more of the hydrogen atoms substituted by a strong oxidizer.

8. A method according to claim 7, wherein the strong oxidizer is fluorine.

9. A method according to claim 1, wherein the gaseous compounds are removed from the ion implantation device by the application of a vacuum.

10. A working molecule comprising at least two boron atoms and at least one strong oxidizer.

11. A working molecule according to claim 10, wherein the strong oxidizer is selected from the group consisting of oxygen, fluorine, chlorine, and an organic acid.

12. A working molecule according to claim 11, wherein the strong oxidizer is oxygen or carboxylic acid.

13. A working molecule according to claim 10, wherein the working molecule fragments to form carborane ions and strong oxidizer during vapor line transmission and under discharge conditions.

14. A working molecule of having the formula C₄H₁₂B₁₀O₄ or C₂B₁₀H₉F₃.

15. A working molecule according to claim 10, wherein the working molecule is 1,7-m-carboranedicarboxylic acid or 1,2-bis(hydroxymethyl)-o-carborane.

16. A working molecule according to claim 10, wherein the working molecule is decacarborane with one or more of the hydrogen atoms substituted by a strong oxidizer, and octadecacarborane with one or more of the hydrogen atoms substituted by a strong oxidizer.

17. A working molecule according to claim 16, wherein the strong oxidizer is fluorine.
